(19) United States
(12) Patent Application Publication
(10) Pub. No.: US 2006/0189029 A1
(43) Pub. Date: Aug. 24, 2006

(54) Method for efficient annealing of plated semiconductor package leads

(76) Inventors: Sreenivasan K. Koduri, Plano, TX (US); Edgar R. Zuniga-Ortiz, McKinney, TX (US)

Correspondence Address: TEXAS INSTRUMENTS INCORPORATED, P O BOX 655474, M/S 3999, DALLAS, TX, 75265, US

(21) Appl. No.: 11/065,689

(22) Filed: Feb. 24, 2005

(51) Int. Cl. H01L 21/44

(52) U.S. Cl. 438/106

(57) ABSTRACT

A method for completing an assembled semiconductor device, which has metallic leads for connection to external parts. The method comprises the step (202) of encapsulating the assembled device with a polymeric precursor so that at least portions of the leads remain un-encapsulated. Without significant delay, these un-encapsulated lead portions are plated (203) with at least one metal layer suitable for connection to external parts; the plating step has no noticeable impact on the uncured mold compound. The encapsulated and plated device is then submitted (204) to a sequence of elevated temperatures for specified periods of time so that concurrently the precursor is polymerized and the at least one metal layer is annealed.

### FIELD OF THE INVENTION

The present invention is related in general to the field of electrical systems and semiconductor devices and more specifically to simplified assembly and packaging processes of molding and plating.

### DESCRIPTION OF THE RELATED ART

It is common practice in the manufacturing technology of semiconductor devices to encapsulate the assembled chip and major portions of the leadframe and then plate any exposed portions of the leadframe with metal layers suitable for device attachment to external parts. Typical metals used for this post-mold-plating step include tin and tin alloys such as tin/lead, tin/silver, tin/indium, tin/bismuth, and tin/silver/copper, nickel-palladium-gold (NiPdAu) and nickel-palladium (NiPd). With the exception of NiPdAu and NiPd, all other materials are expected to whisker; the NiPdAu solutions, however, are not economically available for most of the through-hole packages and some other thermal packages.

While the true nature and reason for whiskering are not fully understood, it has been shown that annealing, the controlled heating and cooling over a long period of time, reduces the stress built up during the plating process and thus reduces the propensity for whiskering significantly. When the annealing is presently performed, it is executed as the final step in the assembly of the packages just before the final testing of the finished devices. This means, however, that another time consuming process step has to be added to the process flow. The added process step is thus expensive. The expense and the inconvenience of the step have so far prevented a wider acceptance of the annealing step in the industry and consequently the benefit of reduced whisker sensitivity for the customer.

### SUMMARY OF THE INVENTION

A need has therefore arisen to evaluate the complete semiconductor device assembly and packaging process flow and identify the feasibility and most practical way of incorporating a plating annealing step in the flow without the disadvantage of an additional time-consuming process step.

One embodiment of the present invention is a method for completing an assembled semiconductor device, which has metallic leads for connection to external parts. The method comprises the steps of encapsulating the assembled device with a polymeric precursor so that at least portions of the leads remain un-encapsulated. Without significant delay, these un-encapsulated lead portions are plated with at least one metal layer suitable for connection to external parts; the plating step has no noticeable impact on the uncured mold compound. The encapsulated and plated device is then submitted to a sequence of elevated temperatures for specified periods of time so that concurrently the precursor is polymerized and the at least one metal layer is annealed.

After the step of the temperature excursion, the exposed lead portions are trimmed and formed; the devices are finally tested and shipped.

A preferred temperature and time sequence consists of a ramp time of approximately 60 min to raise the temperature from ambient temperature of about 175 C; this ramp is followed by a period of about 4 hr at the temperature of about 175 C. The treatment is concluded by a ramp time of about 30 min to lower the temperature from about 175 C to ambient temperature.

In other embodiments, the time for the rising ramp may be about 2 hr, or the time for the falling ramp may be about 15 min. In still other embodiments, the time at the constant high temperature may be between about 2 and 4 hr.

In another embodiment of the invention for devices classified as moisture sensitivity level 2A or above, the plating annealing step may be combined with the moisture bake steps. These baking steps have to be performed before the device packing step; in this case, the plating step may be performed after mold curing.

The invention is of particular technical advantage to Standard Linear and Logic devices, High Performance Analog devices, generally all through-hole and thermal packages, and devices, which for economical reasons cannot use NiPdAu lead finish, but have to employ tin plating.

It is a technical advantage of the invention that not only manufacturing cycle time and cost are reduced, but also the requirements for oven space and thus floor space—but expansive manufacturing items.

It is another technical advantage of the invention that the detail of the assembly process flow is flexible and can easily be adapted to new package configurations and other device families.

The technical advances represented by the invention, as well as the objects thereof, will become apparent from the following description of the preferred embodiments of the invention, when considered in conjunction with the accompanying drawings and the novel features set forth in the appended claims.

### BRIEF DESCRIPTION OF THE DRAWINGS

FIG. 1 is a schematic block diagram the assembly and packaging process flow of a semiconductor device according to an embodiment of the invention.

FIG. 2A is a schematic block diagram of the assembly and packaging process flow of a moisture-rated semiconductor device according to an embodiment of the invention.

FIG. 2B is a schematic block diagram of the assembly and packaging process flow of a moisture-rated semiconductor device according to another embodiment of the invention.

### DETAILED DESCRIPTION OF THE PREFERRED EMBODIMENTS

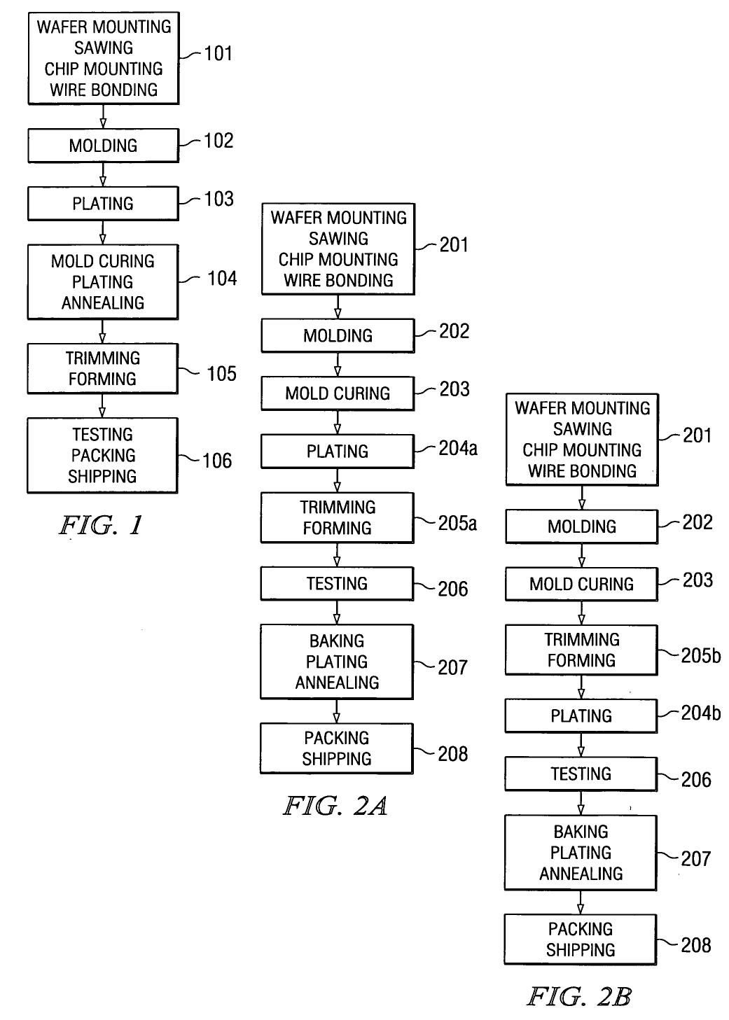

FIG. 1 represents a schematic block diagram of an embodiment of the invention, a method for completing the manufacture of an assembled semiconductor device, which has metallic leads intended for connection to external parts. Block 101 summarizes the process steps after the arrival of the completed semiconductor wafer at an assembly factory: The wafer is first mounted onto a tape and then submitted to a rotating saw for cutting it into individual chips. From the tape, the chips are lifted, one by one, onto a chip mounting machine, which attaches the chip to a metallic leadframe already waiting on this machine. Not mentioned in block 101 is the intermediate process step of polymerizing (“curing”) the polymeric, adhesive attach material, a step which is needed to stabilize the chip for the next process step.

In this step, the leadframe together with the attached semiconductor chips is lifted onto a bonding machine, where the chip's electrical contact pads are wire bonded, one by one, to the segments/leads of the leadframe; preferably, gold wires of about 20 to 25 μm diameter, alloyed with few percent copper, are used.

Block 102 highlights the encapsulation step, which is performed, in the majority of devices, by the transfer molding technique employing thermoset molding compounds, preferably epoxy-based. The compound encapsulates the semiconductor chip, its connecting wires, and portions of the leadframe (such as often the chip mount pad) and the segments, but leaves other portions of the segments/leads un-encapsulated. These un-encapsulated portions serve later for attachment to external parts. Molding step 202 is preferably performed at about 175 C and last preferably between 10 and 60 s.

The molding compounds consist of polymeric precursors enriched with inorganic insulating fillers such as crystallites of silica and alumina; the fillers are uniformly distributed in the polymeric matrix for lowering its coefficient of thermal expansion and adding mechanical strength to the encapsulation. The polymeric precursors require polymerization (cross-linking called “curing”) to harden and obtain the final form and strength. After curing, the molding compound does not soften again.

According to an embodiment of the invention, the curing step is postponed. Rather, without significant delay after cooling the devices from the molding temperature of about 175 C down to ambient temperature, the plating step 103 is initiated. In this step, at least one metal layer suitable for connection to external parts is deposited onto the un-encapsulated portions of the leadframe (segments, leads, rail). Preferred metals include tin, tin alloys such as tin/silver, tin/copper, tin/silver/copper, tin/indium, tin/bismuth, and tin/lead, and indium; examples of multi-layer depositions include nickel-palladium and nickel-palladium-gold. The plating process is a well controlled process and has been shown to have little or no impact on the uncured molding compound.

In process step 104, the encapsulated and plated device is submitted to a sequence of elevated temperatures for specified periods of time so that concurrently the precursor is polymerized and the at least one metal layer is annealed. For the preferred molding compounds and plated metals discussed above, the preferred temperature sequence comprises a ramp-up time of approximately 45 min to raise the temperature from ambient temperature to about 175 C, a period of about 4 hr at about 175 C, and a ramp-down time of approximately 30 min to lower the temperature to ambient temperature. These conditions are equivalent to a ramp-up rate of about 3.4 C/min, a cure time at about 175 C of about 4 hr, and a ramp-down rate of about 3 to 4 C/min. Both ramp times depend on the size of the oven and the amount of oven loading; for large ovens under heavy loading, the ramp times may longer by a factor of 2. The peak temperature may vary by about +5 or −5 C; and the peak time may be 6 hr.

For other device families, the time for ramp-up may be about 2 hr, or the time for ramp-down may be 15 min. In still other device families, the time at the constant high temperature may be between about 2 and 4 hr.

By letting the required polymerization of the molding compound double as the annealing step of the plated metals, the annealed plated metals have only negligible propensity for growing whiskers, and the manufacturing cycle time is considerably shortened and the oven and floor space capacity of the assembly operation noticeably improved. The quality of the devices has been improved. while simultaneously the manufacturing cost has been reduced.

In block 105, the steps of trimming the leadframe and forming the exposed and plated and annealed segments/leads are preformed. The device is then ready for attachment to external parts.

In block 106, the process flow is completed by the steps of final device testing (functional testing), device packing, and device shipping to the user or customer.

Another embodiment of the invention is a method for devices classified as moisture sensitivity level 2A or above; the method is displayed in the two modifications of the schematic block diagram of FIG. 2A and FIG. 2B. According to JEDEC requirements, moisture sensitive devices have to be baked at specified temperatures and for specified periods of time just prior to packing and shipping. Consequently, the step of annealing the plated layers is combined, in this embodiment, with the step of moisture baking. The method of FIG. 2A is preferred over the method of FIG. 2B.

The process steps listed in block 201 are analogous to the steps described above in block 101 of FIG. 1: Mounting of the wafer with the semiconductor devices after completing the wafer fabrication process steps; sawing of the wafer to create the individual chips; mounting of the chips onto metallic lead frames; and wire bonding of the electrical chip contact pads to the segments of the leadframe.

In step 202, the assembled device is encapsulated using a polymeric precursor so that at least portions of the segments/leads remain un-encapsulated. The encapsulation technique is preferably the well-controlled transfer molding technique; it requires in step 203 the polymerization of the thermoset polymeric precursor. The temperatures and times involved in mold curing are analogous to the sequence discussed above in step 104 of FIG. 1; the preferred sequence includes: a ramp-up time of approximately 45 min to raise the temperature from ambient temperature to about 175 C; a period of at least 4 hr at about 175 C; and a ramp-down time of approximately 30 min to lower the temperature to ambient temperature.

Process step 204a in FIG. 2A is the plating of the un-encapsulated segment/lead portions with at least one metal layer suitable for connection to external parts. This step is followed by step 205a, the trimming of the leadframe and the forming of the un-encapsulated portions of the segments/leads. Step 206 pulls forward the final, functional testing of the semiconductor device.

In step 207, the tested device is submitted to a sequence of elevated temperatures for specified periods of time so that concurrently the device is baked to meet specified moisture sensitivity levels and the at least one metal layer is annealed. The preferred sequence comprises a ramp-up time of approximately 60 min to raise the temperature from ambient temperature to about 150 C, a period of at least 4 hr at about 150 C (for some moisture requirements about 6 hr), and a ramp-down time of approximately 60 min to lower the temperature to ambient temperature.

Block 208 includes the steps of packing the device and shipping it to the user.

As in the embodiment of FIG. 1, the technical advantages of merging the plating curing step with the baking step in FIG. 2 are significant. By letting the required moisture baking double as the annealing step of the plated metals, the manufacturing cycle time is considerably shortened and the oven and floor space capacity of the assembly operation noticeably improved. Furthermore, the annealed plated metals have only negligible propensity for growing whiskers.

In the process flow of FIG. 2B, the process step following step 203 of mold curing is the step 205b, in which the leadframe is trimmed and the exposed segments are formed. After completing these actions, the devices run through step 204b, the plating step for depositing at least one metal layer onto the exposed and formed segment portions. Again, the typically plated layer is tin or a tin alloy and is, therefore, prone to develop whiskers, unless an annealing step is performed. In this process flow, the step of annealing the plated layer or layers is postponed in order to be combined with the device baking step in block 207. In FIG. 2B, the steps in blocks 206, 207, and 208 are identical to the steps in blocks 206, 207, and 208 of FIG. 2A.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

We claim:

1. A method for completing an assembled semiconductor device having metallic leads for connection to external parts, comprising the steps of:
encapsulating said assembled device using a polymeric precursor so that at least portions of said leads remain un-encapsulated;
without significant intervening temperature excursion, plating said un-encapsulated lead portions with at least one metal layer suitable for connection to external parts; and
submitting said encapsulated and plated device to a sequence of elevated temperatures for specified periods of time so that concurrently said precursor is polymerized and said at least one metal layer is annealed.

2. The method according to claim 1 further comprising the steps of trimming and forming said exposed lead portions after said step of temperature excursion.

3. The method according to claim 1 wherein said temperature sequence comprises a ramp-up time of approximately 45 min to raise the temperature from ambient temperature to about 175 C, a period of about 4 hr at about 175 C, and a ramp-down time of approximately 30 min to lower the temperature to ambient temperature.

4. The method according to claim 1 wherein said temperature sequence comprises a ramp-up rate of about 3.4 C/min, a cure time at about 175 C of about 4 hr, and a ramp-down rate of about 3 to 4 C/min.

5. The method according to claim 1 wherein said polymeric precursor is a molding compound.

6. The method according to claim 1 wherein said at least one metal layer is a reflow metal, including tin or a tin alloy, suitable for soldering.

7. A method for completing an assembled semiconductor device having metallic leads for connection to external parts, comprising the steps of:
encapsulating said assembled device using a polymeric precursor so that at least portions of said leads remain un-encapsulated;
polymerizing said polymeric precursor;
plating said un-encapsulated lead portions with at least one metal layer suitable for connection to external parts;
trimming and forming said un-encapsulated portions of said leads;
testing said semiconductor device;
submitting said tested device to a sequence of elevated temperatures for specified periods of time so that concurrently said device is baked to meet specified moisture sensitivity level and said at least one metal layer is annealed.

8. The method according to claim 7 wherein said temperature sequence comprises a ramp-up time of approximately 60 min to raise the temperature from ambient temperature to about 150 C, a period of at least 4 hr at about 150 C, and a ramp-down time of approximately 60 min to lower the temperature to ambient temperature.

9. The method according to claim 7 further comprising the steps of packing and shipping said finished device.

10. A method for completing an assembled semiconductor device having metallic leads for connection to external parts, comprising the steps of:
encapsulating said assembled device using a polymeric precursor so that at least portions of said leads remain un-encapsulated;
polymerizing said polymeric precursor;
trimming and forming said un-encapsulated portions of said leads;
plating said un-encapsulated lead portions with at least one metal layer suitable for connection to external parts;
testing said semiconductor device;
submitting said tested device to a sequence of elevated temperatures for specified periods of time so that concurrently said device is baked to meet specified moisture sensitivity levels and said at least one metal layer is annealed.

11. The method according to claim 10 wherein said temperature sequence comprises a ramp-up time of approximately 60 min to raise the temperature from ambient temperature to about 150 C, a period of at least 4 hr at about 150 C, and a ramp-down time of approximately 60 min to lower the temperature to ambient temperature.
